(19) United States
(12) Patent Application Publication
(10) Pub. No.: US 2012/0071000 A1
(43) Pub. Date: Mar. 22, 2012

(54) MANUFACTURING APPARATUS AND METHOD FOR SEMICONDUCTOR DEVICE

(76) Inventor: Hideki ARAI, Numazu-shi (JP)

(21) Appl. No.: 13/226,036

(22) Filed: Sep. 6, 2011

(30) Foreign Application Priority Data
Sep. 22, 2010 (JP) 2010-211720

(51) Int. Cl. H01L 21/31; C23C 16/458; C23C 16/46; C23C 16/455

(52) U.S. Cl. 438/758; 118/725; 257/E21.24

(57) ABSTRACT

A manufacturing apparatus for a semiconductor device, comprising: a reactor chamber configured to load a wafer therein; a gas supplying mechanism configured to supply a process gas into the reactor chamber; a gas discharging mechanism configured to discharge a gas from the reactor chamber; a wafer supporting member configured to mount the wafer thereon; a ring configured to mount the wafer supporting member thereon; a rotary drive controlling mechanism configured to connect to the ring for rotating the wafer; a heater arranged in the ring for heating the wafer to a predetermined temperature; an electrode part configured to connect to the heater and including a screw concave portion; and an electrode including a screw portion which is connected to the electrode part via the screw concave portion.

### CROSS-REFERENCE TO RELATED APPLICATION

This application is based upon and claims the benefit of priority from the prior Japanese Patent Application No. 2010-211720 filed on Sep. 22, 2010, the entire contents of which are incorporated herein by reference.

### BACKGROUND

The present invention relates to manufacturing apparatus and method for a semiconductor device used, for example, for forming a film by heating a semiconductor wafer from its rear face by a heater and supplying a reactant gas to its front face.

In recent years, a high quality such as an improved film thickness uniformity has been required in addition to a high throughput in a film forming process on a wafer accompanied with a request for a cost reduction and a high performance of a semiconductor device.

In order to meet such a request, a rear-face heating system is adopted using a single wafer epitaxial film forming apparatus, such that a process gas is supplied while the wafer is rotated, for example, at a high speed of 900 rpm or more in a reactor, followed by heating the wafer from the rear face by using the heater.

At this occasion, as is disclosed in Japanese Patent Application Laid-Open No. 2007-288163 ([FIG. 1], [FIG. 2], etc.), the heater is connected to an electrode part formed, for example, of SiC coated carbon, etc. Further, the electrode part is connected to an exterior power source by making a surface contact with an electrode connected to the exterior power source that supplies electricity to the heater, and is fixed by bolts, etc.

### SUMMARY

A manufacturing apparatus of one aspect of the present invention including: a reactor chamber configured to load a wafer therein; a gas supplying mechanism configured to supply a process gas into the reactor chamber; a gas discharging mechanism configured to discharge a gas from the reactor chamber; a wafer supporting member configured to mount the wafer thereon; a ring configured to mount the wafer supporting member thereon; a rotary drive controlling mechanism configured to connect to the ring for rotating the wafer; a heater arranged in the ring for heating the wafer to a predetermined temperature; an electrode part configured to connect to the heater and including a screw concave portion; and an electrode including a screw portion which is connected to the electrode part via the screw concave portion.

A manufacturing method for a semiconductor device of one aspect of the present invention including: loading a wafer in a reactor chamber; heating the wafer at a predetermined temperature by supplying electricity from an electrode to a heater via an electrode part including a screw concave portion connected to a screw portion provided in the electrode, and generating heat in the heater; and forming a film on the wafer by rotating the wafer and supplying a process gas over the wafer.

### BRIEF DESCRIPTION OF THE DRAWINGS

FIG. 1 is a cross sectional diagram showing a structure of an epitaxial film forming apparatus of an aspect of the present invention;

FIG. 2A is an enlarged cross sectional diagram of a connecting portion of a booth bar with an electrode of FIG. 1;

FIG. 2B is an enlarged cross sectional diagram of a connecting portion of the electrode with the booth bar of FIG. 1;

FIG. 3 is a cross sectional diagram showing a structure of an epitaxial film forming apparatus of an aspect of the present invention; and

FIG. 4 is a cross sectional diagram showing a structure of a connecting portion of an electrode with a booth bar of an aspect of the present invention.

### DETAILED DESCRIPTION

Reference will now be made in detail to the present embodiment of the invention, an example of which is illustrated in the accompanying drawings.

Hereinbelow, embodiments of the present invention will be described with reference to the drawings.

### First Embodiment

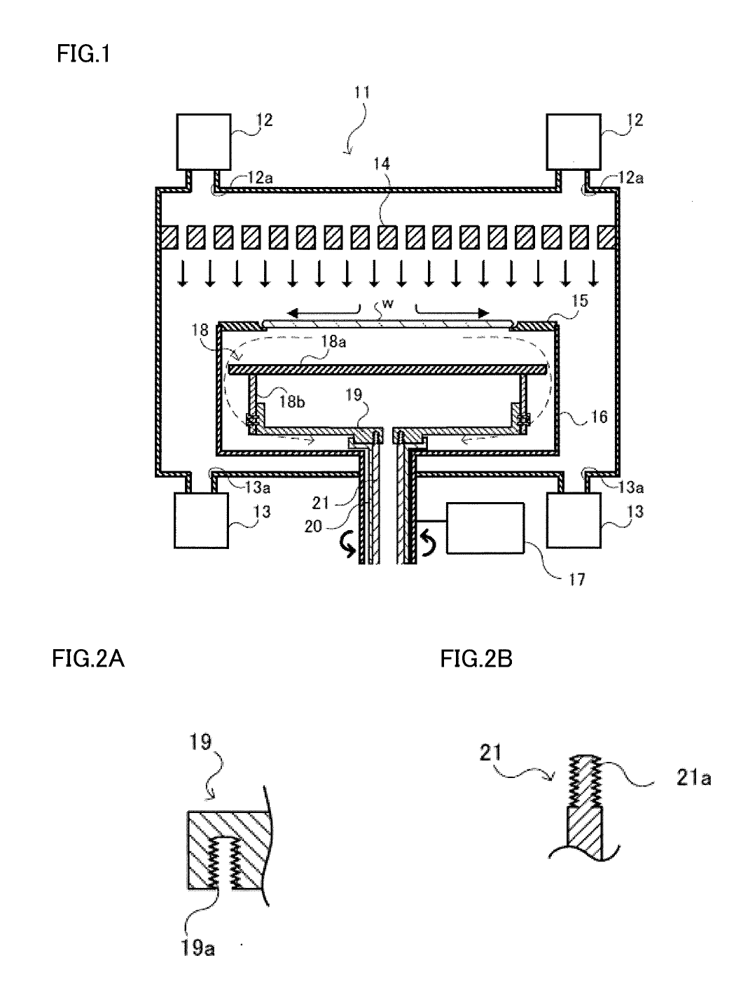

FIG. 1 shows across sectional diagram of an epitaxial film forming apparatus, which is a semiconductor manufacturing apparatus of the present embodiment. As shown in the FIG. 1, gas supply ports 12a connected to a gas supplying mechanism 12 for supplying a process gas containing a source gas such as trichlorosilane, dichlorosilane, etc. over a wafer w at a predetermined flow rate from an upper portion of a reactor chamber 11 are provided in the reactor chamber 11 in which the wafer w, for example, of φ200 mm is to undergo a film forming process. At a lower portion of the reactor chamber 11, for example, at two portions, gas discharge ports 13a connected to a gas discharging mechanism 13 for discharging a gas and controlling a pressure inside the reactor chamber 11 at a constant value (normal pressure) are provided.

Rectifying plates 14 for supplying the process gas supplied through the gas supply ports 12a over the wafer w in a rectified state are provided in the upper portion of the reactor chamber 11. Further, under the rectifying plates 14, an annular holder 15 that is a wafer supporting member for supporting the wafer w is provided on a ring 16. The ring 16 is connected to a rotary drive controlling mechanism 17 configured of a rotary shaft (not shown) that rotates the wafer w at a predetermined rotational speed, a motor (not shown), etc.

A heater 18 for heating the wafer w is provided inside the ring 16. The heater 18 has a predetermined pattern, and is configured of a circular-plate shaped heater element 18a formed of SiC, and a heater electrode portion 18b that is formed integrally with the heater element. The heater electrode portion 18b is formed of SiC having conductivity due to impurities being added, and further an SiC film is coated thereon. As the heater, an annular heater may further be used, and a reflector for an efficient heating may be included.

A booth bar 19 formed, for example, of SiC coated carbon, which is an electrode part connected to the heater electrode portion 18b is provided at a lower portion inside the ring 16. The booth bar 19 is connected to an electrode 21, for example, formed of Mo.

FIG. 2A shows an enlarged diagram of a connecting portion of the booth bar 19, and FIG. 2B shows an enlarged diagram of a connecting portion of the electrode 21. As shown in the drawings, at a distal end of the booth bar 19, a screw concave portion 19a where carbon is exposed is provided. On the other hand, at a distal end of the electrode 21, a screw portion 21a is provided, and the booth bar 19 and the electrode 21 are connected by screwing the screw portion 21a of the electrode 21 into the screw concave portion 19a of the booth bar 19.

The electrode 21 that is connected accordingly with the booth bar 19 is fixed to a heater shaft 20, and is connected to an exterior power source (not shown) that supplies power to the heater.

By using the epitaxial film forming apparatus configured as above, an Si epitaxial film is formed, for example, on the Si wafer w of φ200 mm.

The wafer w is loaded into the reactor chamber 11, and the holder 15 onto which the wafer w is mounted is mounted on the ring 16. Then, by the electrode 21 connected to the exterior power source (not shown), electricity is supplied to the heater electrode portion 18b and the heater element 18a via the booth bar 19. At this occasion, the booth bar 19 and the electrode 21 are electrically connected by the screw concave portion 19a of the booth bar 19 and the screw portion 21a of the electrode 21.

The electricity is supplied to the heater element 18a accordingly, and a temperature of the heater element 18a is controlled at 1500 to 1600° C. such that an in-plane temperature of the wafer w is uniform, for example, at 1100° C.

By using the rotary drive controlling mechanism 17, the wafer w is rotated, for example, at 900 rpm, and the process gas is supplied from the gas supplying mechanism 12 via the gas supply ports 12a to over the wafer w in the rectified state via the rectifying plates 14. The process gas is diluted with a dilution gas such as H₂ such that a concentration of dichlorosilane is adjusted, for example, to 2.5%, and is supplied, for example, at 50 SLM. At this occasion, although the process gas flows around as shown in broken arrows in the ring, since a connecting interface is provided in the screw concave portion 19a, the flow-around to the connecting interface can be suppressed.

On the other hand, a gas including dichlorosilane in excess, the process gas containing the dilution gas, and HCl as a reaction by-product, etc. is discharged downward from an outer circumference of the holder 15. Further, the gas is discharged through the gas discharging mechanism 13 via the gas discharge ports 13a so that the pressure inside of the reactor chamber 11 is controlled to be constant (e.g. at the normal pressure). In this manner, the Si epitaxial film is grown on the wafer w.

Conventionally, an electrode part connected to a heater is connected to an electrode connected to an exterior power source, however, a process gas flows around to a connecting interface of the electrode part and the electrode and reacts thereat, and a problem that the connecting interface is ruined has been occurring. Further, by a part of the connecting interface becoming swelled, an electrified area is reduced and thereby a resistance is increased, and the connecting interface is further ruined by a discharge at a separated portion. Then, there is a problem that productivity is decreased due to replacements of parts becoming necessary.

This kind of phenomenon becomes significant in cases of rotating the wafer at a high speed of 500 to 1500 rpm, because the flow-around of the discharge gas such as the process gas becomes more likely to occur at portions underneath the wafer. Further, the aforementioned is considered to become more likely to occur by increasing. a concentration of a film forming gas in the process gas. However, if the rotation of the wafer or the concentration of the film forming gas is reduced, a throughput and uniformity in the formed film are decreased.

According to the present embodiment, the electrode is directly screwed into the booth bar and is thereby connected electrically, so that the flow-around of the process gas to the connecting interface can be suppressed. Further, since the ruin of the connecting interface can be suppressed, a frequency by which the parts are to be replaced can be reduced. Accordingly, a high performance and an improvement in reliability, productivity and a low cost of the semiconductor device can be achieved without decreasing the throughput and the uniformity in the formed film.

### Second Embodiment

In the present embodiment, although a configuration of an epitaxial film forming apparatus is identical to that in the first embodiment, a cover member covering a connecting portion of a booth bar and an electrode is provided.

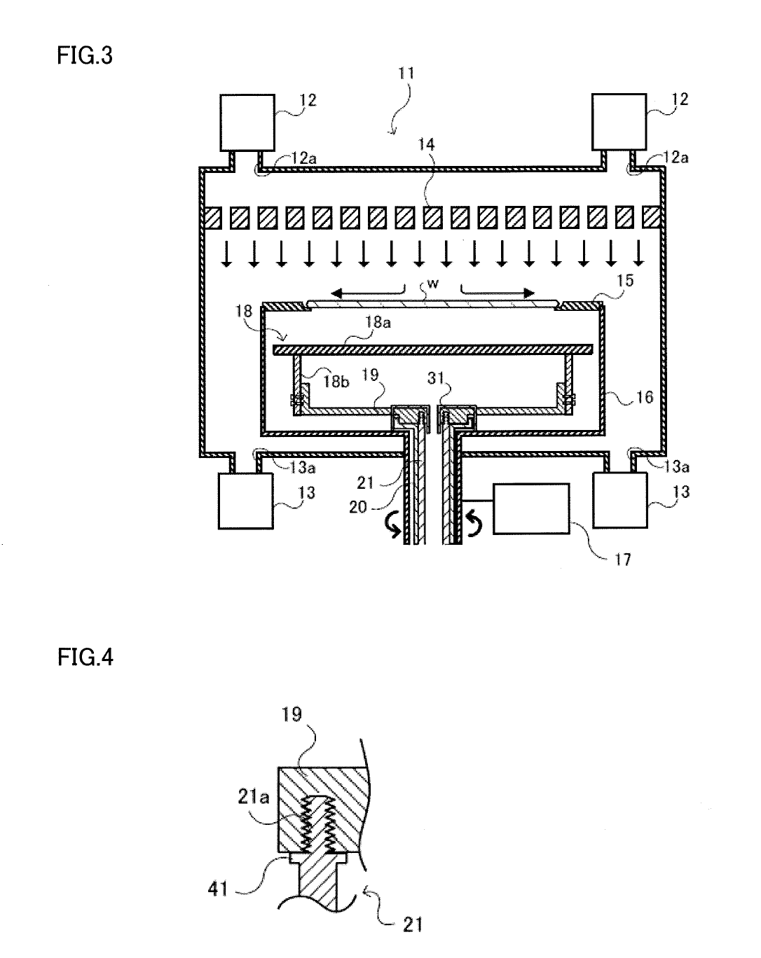

That is, as shown in FIG. 3, the cover member 31 formed, for example, of quartz and covering the connecting portion of the booth bar 19 and the electrode 21, i.e. a portion where a screw portion 21a of an electrode 21 is screwed into a screw concave portion 19a of a booth bar 19, is provided. Further, by the cover member 31, the flow-around of a process gas to a connecting interface of the booth bar 19 and the electrode 21 can be more surely suppressed.

According to the present embodiment, since the flow-around of the process gas can be more surely suppressed, even a higher effect than that of the first embodiment can be achieved.

### Third Embodiment

In the present embodiment, although a configuration of an epitaxial film forming apparatus is identical to that in the first embodiment, a projection is arranged under a screw portion of an electrode.

As an enlarged diagram of a connecting portion is shown in FIG. 4, the projection 41 is arranged under the screw portion 21a of the electrode 21, which is the connecting portion of a booth bar 19 and an electrode 21. By the projection 41, the flow-around of a process gas to a connecting interface of the booth bar 19 and the electrode 21 can be more surely suppressed.

According to the present embodiment, since the flow-around of the process gas can be more surely suppressed, even a higher effect than that of the first embodiment can be achieved. Further, the cover member of the second embodiment may be provided together with the projection of the present embodiment. The effect of suppressing the flow-around of the discharge gas such as the process gas can further be improved.

According to the present embodiment, it becomes possible to stably produce high quality films such as an epitaxial film on a semiconductor wafer w with high productivity. Further, along with an improvement in a yield of wafers, it becomes possible to realize an improvement in a yield of semiconductor devices that are formed through an element forming step and an element isolating step, and a stability of element properties thereof. Especially, it becomes possible to achieve a satisfactory element property by being adapted to an epitaxial forming step for a power semiconductor device such as a power MOSFET or an IGBT, in which a forming of a thick film of 40 μm or more is required in an N-type base region, a P-type base region, an electrically isolated region, etc.

Further, in the present embodiments, cases of forming Si monocrystal layer (epitaxial film) have been explained, however, the present embodiments can be applied to cases of forming a poly-Si layer. Further, they may be applied, for example, to a film forming other than the Si, such as an SiO₂ and an film, and may further be applied to a compound semiconductor film forming such as a GaAs, GaAlAs and InGaAs. Other implementations can be made with various modifications within a scope without departing from the gist of the invention.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A manufacturing apparatus for a semiconductor device, comprising:
a reactor chamber configured to load a wafer therein;
a gas supplying mechanism configured to supply a process gas into the reactor chamber;
a gas discharging mechanism configured to discharge a gas from the reactor chamber;
a wafer supporting member configured to mount the wafer thereon;
a ring configured to mount the wafer supporting member thereon;
a rotary drive controlling mechanism configured to connect to the ring for rotating the wafer;
a heater arranged in the ring for heating the wafer to a predetermined temperature;
an electrode part configured to connect to the heater and including a screw concave portion; and
an electrode including a screw portion which is connected to the electrode part via the screw concave portion.

2. The manufacturing apparatus for a semiconductor device according to claim 1, further comprising a cover member configured to cover a connecting portion of the electrode part and the electrode.

3. The manufacturing apparatus for a semiconductor device according to claim 2, wherein the cover member is formed of quartz.

4. The manufacturing apparatus for a semiconductor device according to claim 1, wherein the electrode includes a projection under the screw portion.

5. The manufacturing apparatus for a semiconductor device according to claim 2, wherein the electrode includes a projection under the screw portion.

6. The manufacturing apparatus for a semiconductor device according to claim 1, wherein the electrode part is SiC coated carbon.

7. The manufacturing apparatus for a semiconductor device according to claim 1, wherein the electrode is formed of Mo.

8. The manufacturing apparatus for a semiconductor device according to claim 1, wherein the process gas includes a source gas and a carrier gas.

9. The manufacturing apparatus for a semiconductor device according to claim 1, wherein the source gas includes one of trichlorosilane and dichlorosilane.

10. A manufacturing method for a semiconductor device, comprising:
loading a wafer in a reactor chamber;
heating the wafer at a predetermined temperature by supplying electricity from an electrode to a heater via an electrode part including a screw concave portion connected to a screw portion provided in the electrode, and generating heat in the heater; and
forming a film on the wafer by rotating the wafer and supplying a process gas over the wafer.

11. The manufacturing method for a semiconductor device according to claim, wherein the wafer is rotated at 500 to 1500 rpm.

12. The manufacturing method for a semiconductor device according to claim 10, wherein the process gas in excess flows around to underneath the wafer.

13. The manufacturing method for a semiconductor device according to claim 10, wherein the electrode part is SiC coated carbon.

14. The manufacturing method for a semiconductor device according to claim 10, wherein the electrode is formed of Mo.

15. The manufacturing method for a semiconductor device according to claim 10, wherein a flow-around of the process gas is suppressed by a cover member covering a connecting portion of the electrode part and the electrode.

16. The manufacturing apparatus for a semiconductor device according to claim 15, wherein the cover member is formed of quartz.

17. The manufacturing method for a semiconductor device according to claim 10, wherein a flow-around of the process gas is suppressed by a projection arranged under the screw portion of the electrode.

18. The manufacturing method for a semiconductor device according to claim 15, wherein a flow-around of the process gas is suppressed by a projection arranged under the screw portion of the electrode.

19. The manufacturing method for a semiconductor device according to claim 10, wherein the process gas includes a source gas and a carrier gas.

20. The manufacturing method for a semiconductor device according to claim 19, wherein the source gas includes one of trichlorosilane and dichlorosilane.
